(19) United States
(12) Patent Application Publication
(10) Pub. No.: US 2010/0124800 A1
(43) Pub. Date: May 20, 2010

(54) VARIABLE RESISTANCE MEMORY DEVICE, METHOD OF FABRICATING THE SAME, AND MEMORY SYSTEM INCLUDING THE SAME

(75) Inventors: Jeonghee Park, Hwasung-si (KR); Sunglae Cho, Gwacheon-si (KR); Yongho Ha, Hwasung-si (KR); Hyun-Suk Kwon, Seoul (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/617,754

(22) Filed: Nov. 13, 2009

(30) Foreign Application Priority Data
Nov. 17, 2008 (KR) 10-2008-0114028

(51) Int. Cl. H01L 21/06

(52) U.S. Cl. 438/102; 257/E21.068

(57) ABSTRACT

A method of fabricating a variable resistance memory device includes a plasma etching process to remove contaminants from variable resistance material that forms variable resistance elements of the device. Bottom electrodes are formed on a semiconductor substrate. Next, an interlayer dielectric layer having trenches that expose the bottom electrodes is formed on the substrate. Then a layer of variable resistance material is formed. The variable resistance material covers the interlayer dielectric layer and fills the trenches. The variable resistance material is then planarized down to at least the top surface of the interlayer dielectric layer, thereby leaving elements of the variable resistance material in the trenches. The variable resistance material in the trenches is etched to remove contaminants, produced as a result of the planarizing process, from atop the variable resistance material in the trenches. A top electrode is then formed on the variable resistance material.

### CROSS-REFERENCE TO RELATED APPLICATION

This U.S. non-provisional patent application claims priority under 35 U.S.C §119 to Korean Patent Application No. 10-2008-0114028, filed on Nov. 17, 2008.

### BACKGROUND

The present inventive concept relates to semiconductor memory devices. More specifically, the present inventive concept relates to variable resistance memory devices, to methods of fabricating the same, and to memory system including variable resistance memory devices.

Semiconductor memory devices may be classified as volatile memory devices or nonvolatile memory devices. Volatile memory devices lose their stored data when their power supplies are interrupted, while nonvolatile memory devices retain their stored data even when their power supplies are interrupted. Examples of volatile memory devices are dynamic random access memory (DRAM) devices and static random access memory (SRAM) devices. Examples of nonvolatile memory devices are programmable ROM (PROM) devices, erasable PROM (EPROM) devices, electrically EPROM (EEPROM) devices, and variable resistance memory devices.

Variable resistance memory devices use a resistive material, such as phase change material, ferroelectric material, or magnetic material to store data. An example of a variable resistance memory device using a resistive material is a phase change random access memory (PRAM). PRAM devices are among the next generation of nonvolatile memory devices which offer high performance and low power dissipation. A PRAM device utilizes a phase change material whose resistance varies according to current or voltage. The phase change material maintains its resistance even when the supply of current or voltage is cut off.

### SUMMARY

The inventive concept provides a method of fabricating a variable resistance memory device in which an etching process is used to remove contaminants from variable resistance material that forms variable resistance elements of the device. Bottom electrodes are formed on a semiconductor substrate. Also, an interlayer dielectric layer having trenches that expose the bottom electrodes is formed on the substrate. Next, variable resistance material is deposited on the interlayer dielectric layer to such a thickness as to fill the trenches and cover the interlayer dielectric layer. The variable resistance material is planarized to remove it from atop the interlayer dielectric layer and leave elements of variable resistance material in the trenches, respectively. The planarizing process produces contaminants on the variable resistance material in the trenches. Subsequently, contaminants are removed from the variable resistance material by etching the variable resistance material. Then, a top electrode is formed on the variable resistance material.

### BRIEF DESCRIPTION OF THE DRAWINGS

Other aspects and features of the inventive concept will become more apparent from the detailed description of embodiments thereof that follow, made in conjunction with the accompanying drawings.

FIG. 1 is a block diagram of a memory system having a variable resistance memory embodied according to the present inventive concept.

FIG. 2 is a circuit diagram of a memory cell array of the variable resistance memory of the system shown in FIG. 1.

FIG. 3 is a graph illustrating operational characteristics of the variable resistance memory devices of the array shown in FIG. 2.

FIG. 4 is a plan view of an embodiment of a memory cell array of a variable resistance memory according to the inventive concept.

FIG. 5 is a cross-sectional view taken along line A-A′ in FIG. 4.

FIG. 6 is a cross-sectional view taken along line B-B′ in FIG. 4.

FIG. 7 is a plan view of another embodiment of a memory cell array of a variable resistance memory according to the inventive concept.

FIG. 8 is a cross-sectional view taken along line A-A′ in FIG. 7.

FIG. 9 is a cross-sectional view taken along line B-B′ in FIG. 7.

FIG. 10 is a plan view of still another embodiment of a memory cell array of variable resistance memory devices according to the inventive concept.

FIG. 11 is a cross-sectional view taken along line A-A′ in FIG. 10.

FIG. 12 is a cross-sectional view taken along line B-B′ in FIG. 10.

FIGS. 13A to 25A are cross-sectional views of a substrate, each taken in the same direction as line A-A′ in FIG. 4, and which together illustrate an embodiment of a method of fabricating a variable resistance memory cell array according to the inventive concept.

FIGS. 13B to 25B are cross-sectional views of a substrate, each taken in the same direction as line B-B′ in FIG. 4, and which together also serve to illustrate an embodiment of a method of fabricating a variable resistance memory cell array according to the inventive concept.

FIGS. 26 to 30 are each a graph of a performance test of variable resistance memory cells according to an etching process for removing contaminants.

FIG. 31 is a block diagram of a computer including a memory system of the type shown in FIG. 1.

### DETAILED DESCRIPTION OF THE PREFERRED EMBODIMENTS

Embodiments of a variable resistance memory device and method of fabricating the same, according to the inventive concept, will now be described more fully hereinafter with reference to accompanying drawings. The same reference numerals are used to designate like elements throughout the drawings depicting each embodiment. Also, in the drawings, the sizes and relative sizes of components, layers and structures (elements) may be exaggerated for clarity. In particular, cross-sectional views are schematic in nature and thus illustrate at least some of the elements in an idealized manner. As such, the shapes of at least some of the elements in an actual memory device embodied or fabricated in accordance with the inventive concept may vary from those illustrated due, for example, to manufacturing techniques and/or tolerances.

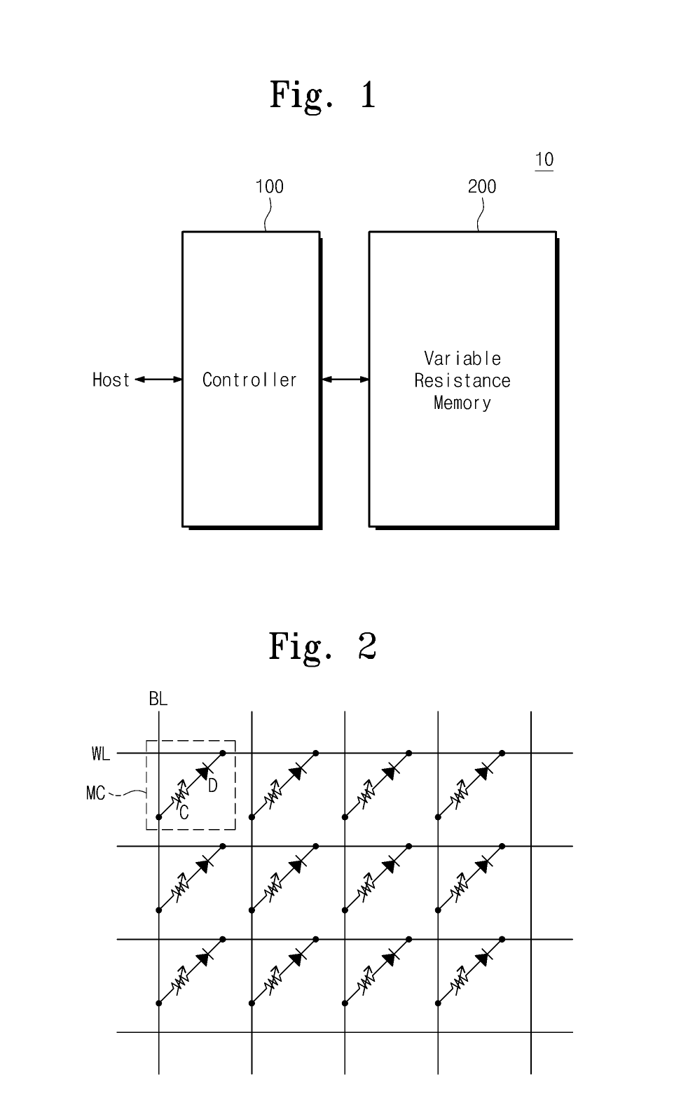

Referring to FIG. 1, a memory system 10 includes a variable resistance memory 200 and a controller 100. The controller 100 is connected to a host and to the variable resistance memory 200. The controller 100 transmits data read from the variable resistance memory 200 to the host and transmits data to be stored from the host to the variable resistance memory 200. The controller 100 may be made up of conventional components such as a RAM, a processing unit, a host interface, and a memory interface.

In this case, the RAM may store data for use in operating the processing unit. The processing unit may control all operations of the controller 100. The host interface provides the protocol for the exchanging of data between the host and the controller 100. Thus, the controller 100 is configured to communicate with the outside (host) through an interface protocol such as a USB, MMC, PCI-E, ATA (Advanced Technology Attachment), Serial-ATA, Parallel-ATA, ESDI, or IDE (Integrated Drive Electronics). The controller 100 may also include an error correction block which detects and corrects errors of data read from the variable resistance memory device.

The variable resistance memory 200 includes a memory cell array in which data is stored. The variable resistance memory 200 may also include a read/write circuit configured to read/write data from/to the memory cell array, an address decoder that decodes externally transmitted data and transmits the decoded data to the read/write circuit, and a control logic that controls all of the operations of the variable resistance memory 200.

The controller 100 and the variable resistance memory 200 may be integrated so as to constitute a self-contained (one) memory device. As an example, the controller 100 and the variable resistance memory device 200 may constitute a memory card. As specific examples, the controller 100 and the variable resistance memory device 200 may constitute a PC card (PCMCIA), a smart media card (SM/SMC), a memory stick, a multimedia card (MMC, RS-MMC, and MMCmicro), or an SD card (SD, miniSD, and microSD).

In another embodiment, the controller 100 and the variable resistance memory device 200 are integrated so as to constitute a solid-state disk/drive (SSD). In the case where the memory system 10 is used as an SSD, the operating speed of the host connected to the memory system 10 can be significantly enhanced.

In yet other embodiments, the variable resistance memory 200 or the memory system 10 constitute a package. Examples of such packages include a PoP (Package on Package), a Ball Grid Array (BGA) package, a Chip Scale Package (CSP), a Plastic Leaded Chip Carrier (PLCC), a Plastic Dual In-Line Package (PDIP), a Die in Waffle Pack, a Die in Wafer Form, a Chip On Board (COB), a Ceramic Dual In-Line Package (CERDIP), a Plastic Metric Quad Flat Pack (MQFP), a Thin Quad Flat Pack (TQFP), a Small Outline Integrated Circuit (SOIC), a Shrink Small Outline Package (SSOP), a Thin Small Outline Package (TSOP), a Thin Quad Flat Pack (TQFP), a System In Package (SIP), a Multi-Chip Package (MCP), a Wafer-Level Fabricated Package (WFP), and a Wafer-Level Processed Stack Package (WSP).

FIG. 2 shows a memory cell array of the variable resistance memory 200. The memory cell array is provided with a plurality of bitlines BL and a plurality of wordlines WL. Memory cells are disposed at intersections of the bitlines BL and the wordlines WL. Each of the memory cells includes a variable resistance element C and a select element D. The variable resistance element C is coupled between a bitline BL and select element D, and the select element D is coupled between the variable resistance element C and a wordline WL.

The variable resistance element C comprises a resistive material. For example, the resistive material is a phase change material, a ferroelectric material, or a magnetic material. A logic level of the variable resistance element C can be set according to the amount of current supplied through a bitline BL.

The select element D, coupled between the variable resistance element C and a wordline WL, controls the amount of current supplied to the variable resistance element C from a bitline BL. As shown FIG. 1, the select element D is a diode. Alternatively, the select element D may be a MOS transistor or a bipolar transistor.

Embodiments of the inventive concept will be described hereinafter with reference to a variable resistance memory device having phase change material as its variable resistance element C. However, the inventive concept is not so limited but also pertains to other types of variable resistance memory devices. That is, the inventive concept also pertains to variable resistance memory devices having a variable resistance element of ferroelectric or magnetic material.

Phase change material may assume either an amorphous state or a crystalline state depending on its temperature. Also, the resistance of phase change material is higher in its amorphous state than in its crystalline state. When current is supplied to phase change material, Joule's heat is generated at the phase change material. Thus, the resistance of the phase change material can be changed by changing the amount of Joule's heat generated at the phase change material, i.e., the resistance of the phase change material can be controlled by controlled the amount of current supplied to the phase change material.

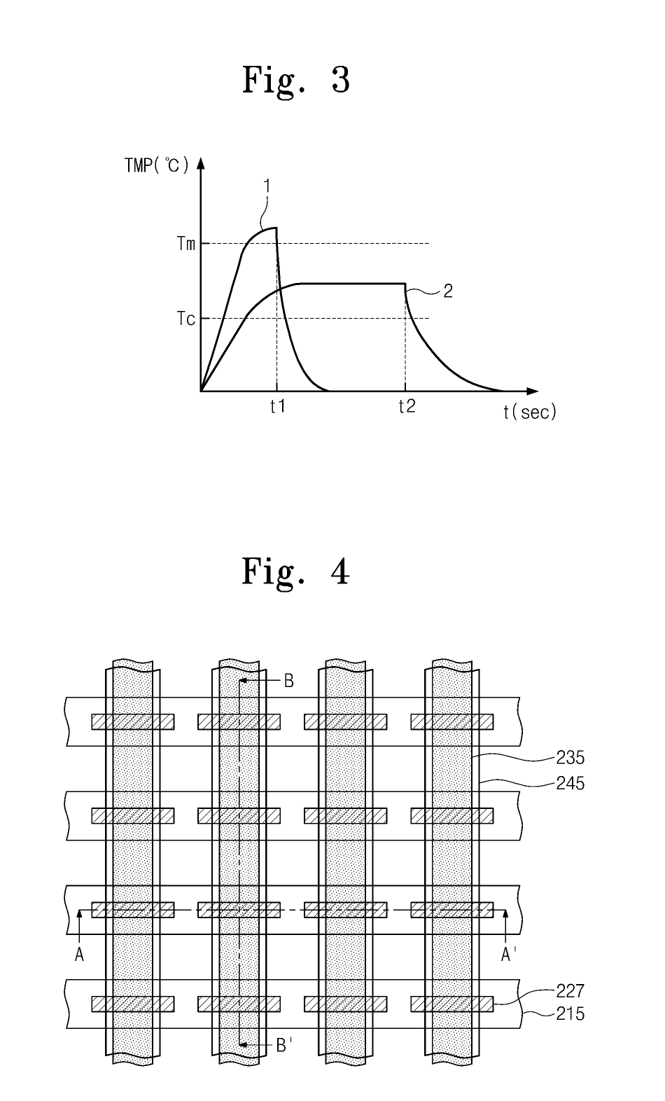

FIG. 3 is a graph illustrating operational characteristics of the variable resistance memory cells MC shown in FIG. 2. Referring to FIG. 3, phase change material (i.e., a variable resistance element) assumes an amorphous state when it is rapidly quenched after being heated to a high temperature above its melting point Tₘ for a time t1. The amorphous state corresponds to a reset state or a state (logic level) in which data ‘1’ is stored. On the other hand, the phase change material assumes a crystalline state when it is slowly quenched after being heated to a low temperature below its melting point Tₘ for a time t2 longer than the time t1. The crystalline state corresponds to a set state or a state (logic level) in which data ‘0’ is stored.

A memory cell array of a variable resistance memory according to an example of the inventive concept will now be described with reference to FIGS. 4 to 6.

The memory cell array has a semiconductor substrate 210, and wordlines 215 extending in a first direction on the semiconductor substrate 210. The wordlines 215 may be lines of material that are doped with impurities so as to be electrically conductive.

A bottom insulating first layer 220 including insulating material and bottom electrodes 227 is disposed on the semiconductor substrate 210. The bottom electrodes 227 may be in the form of dashes spaced from one another throughout the insulating material of the bottom insulating first layer 220. More specifically, each bottom electrodes 227 may have a major axis and a minor axis. Respective sets of the bottom electrodes 227 are disposed on each respective wordline 215, the bottom electrodes 227 of each set are spaced apart from each other by a predetermined distance along the wordline 215, and the bottom electrodes 227 each extend linearly on the wordline 215. Thus, the major axes of the bottom electrodes 227 are parallel to the wordlines 215.

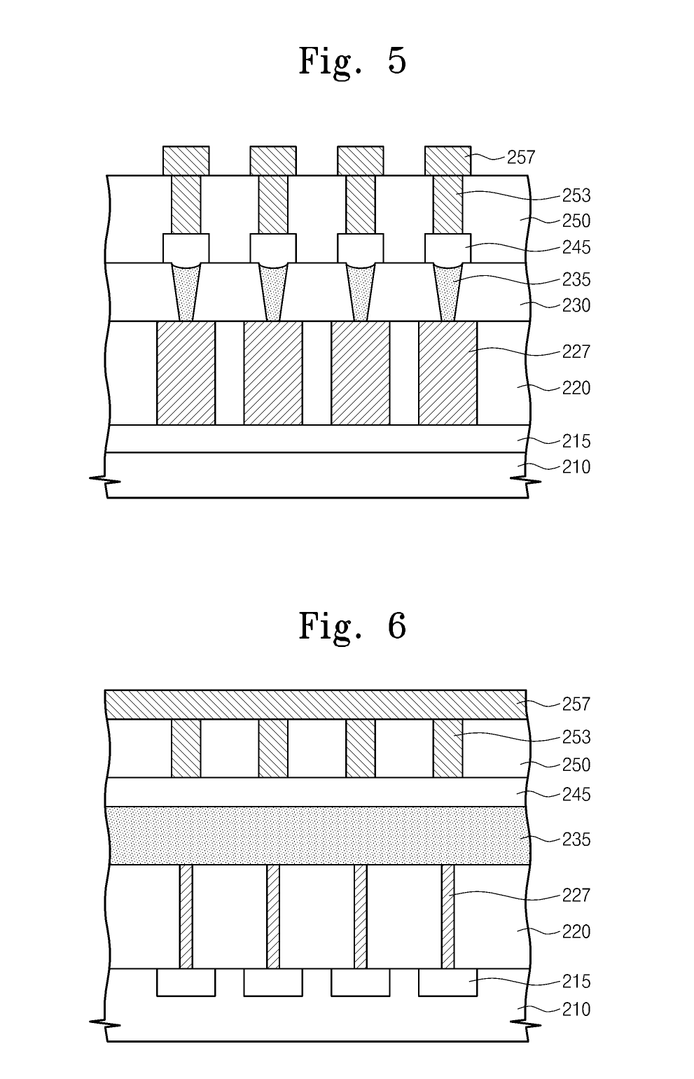

The bottom electrodes 227 may be connected to the select elements (D in FIG. 2) such as diodes or transistors, respectively. FIGS. 5 and 6 show the wordlines 215 directly connected to bottom electrodes 227. However, the select elements (D in FIG. 2) may be provided between the wordlines 215 and the bottom electrodes 227, respectively.

An interlayer dielectric second layer 230 containing the phase change material 235 (hereinafter referred to as “variable resistance elements”) is provided on the first bottom insulator layer 220. The variable resistance elements 235 extend transversely with respect to the wordlines 215, i.e., the variable resistance elements 235 and the wordlines 215 cross one another. In addition, the bottom electrodes 227 are disposed at intersections of the vertical planes in which the variable resistance elements 235 and the wordlines 215 lie.

In this embodiment, the variable resistance elements 235 have the form of lines. However, the inventive concept is not so limited. For example, the variable resistance elements 235 may have an isolation-type of pattern instead of a line pattern. That is, the variable resistance elements 235 may be in the form of islands of phase change material disposed on the bottom electrodes 227, respectively.

An interlayer dielectric third layer 250 including top electrodes 245 is disposed on the interlayer dielectric second layer 230. The top electrodes 245 are connected to the variable resistance elements 235. In particular, the top electrodes 245 may be linearly extending conductive elements spaced apart from each other by a predetermined distance over the region at which the respective variable resistance elements 235 are disposed.

Conductor lines 257 are disposed on the interlayer dielectric third layer 250. The conductive lines 257 extend transversely of the wordlines 215 and parallel to the variable resistance elements 235. The conductor lines 257 are connected to the top electrodes 245 through vias 253, respectively. The conductor lines 257 may serve as bitlines (for example, as bitlines BL in the embodiment of FIG. 2).

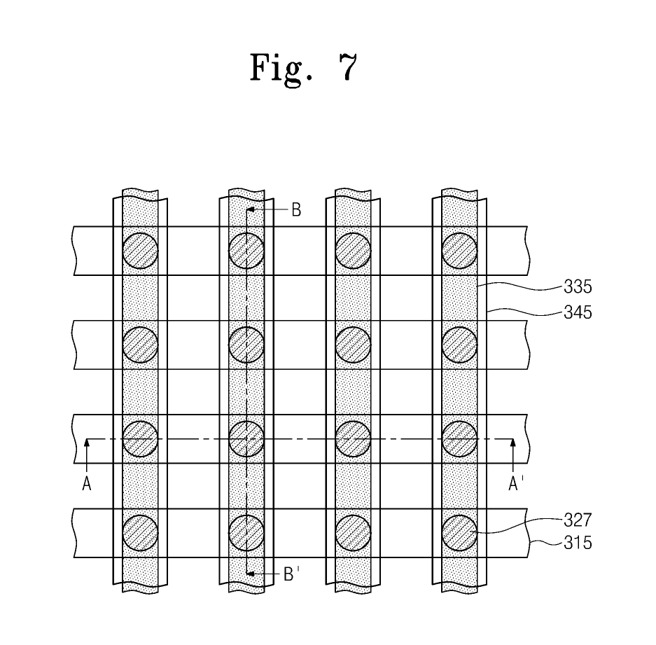

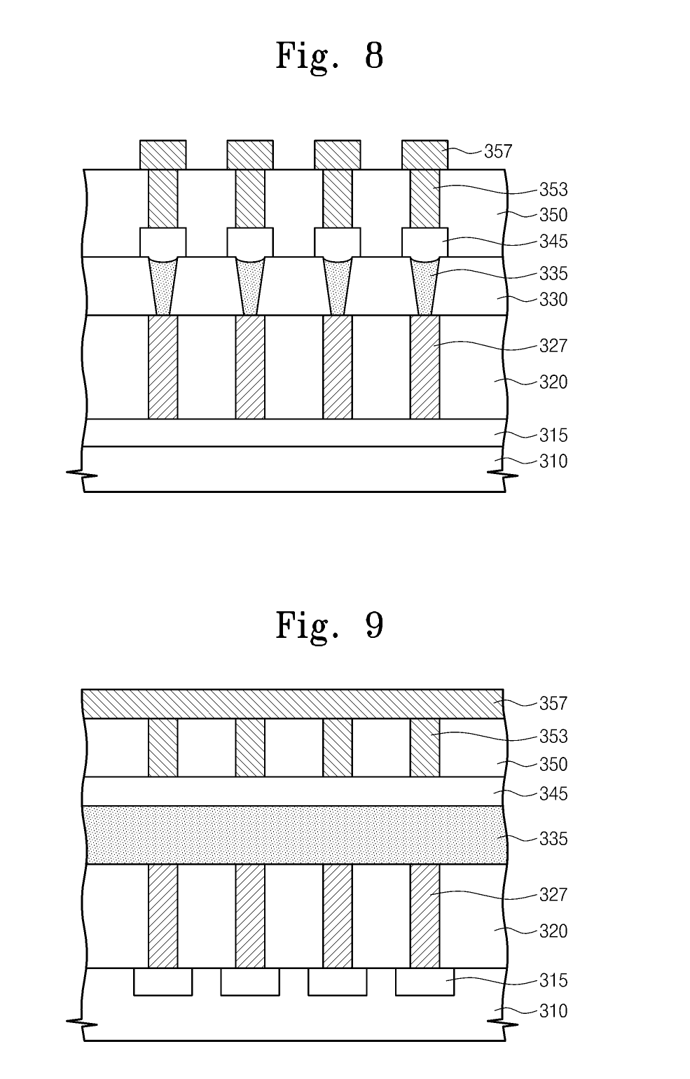

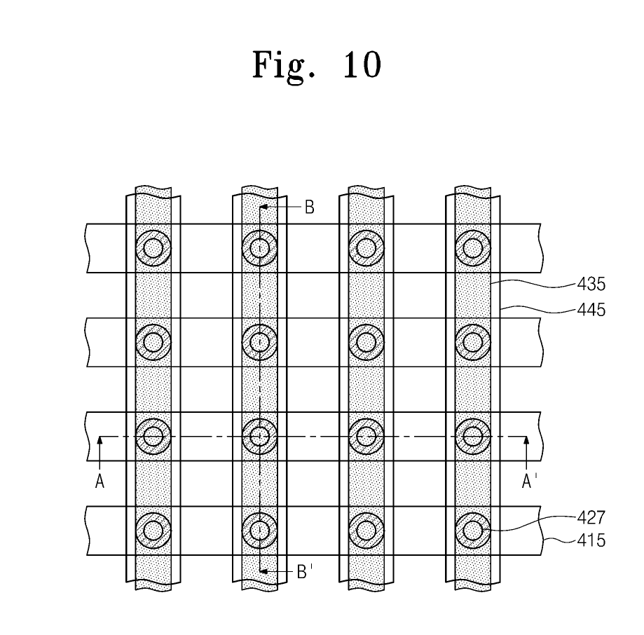

FIGS. 7, 8 and 9 show another example of a memory cell array according to the inventive concept. The memory cell array shown in FIGS. 7 to 9 is substantially identical to that shown in FIGS. 4 to 6 except for the shape of bottom electrodes. Therefore, only the part of the memory cell array including the bottom electrodes will be described in detail and elements which are similar to those of the memory cell array shown in FIGS. 4 to 6 will be designated by similar reference numerals except that the reference numeral used in FIGS. 7 to 9 will be preceded by the number “3” instead of the number “2”.

A respective set of bottom electrodes 327 is disposed on each wordline 315. Also, the bottom electrodes 327 in each set are spaced apart from each other by a predetermined distance along the length of the respective wordline 315. Therefore, the bottom electrodes 327 are disposed on the wordlines 315 in a matrix. Also, the bottom electrodes 327 may be in the form of right circular or quadrangular pillar. In this case, a spacer (not shown) may be provided along the circumference of the pillar-shaped bottom electrode 327. Such a spacer would reduce the diameter of the pillar-shaped bottom electrode 327. In any case, the width of each of the bottom electrodes 327 is smaller than that of each of the wordlines 315.

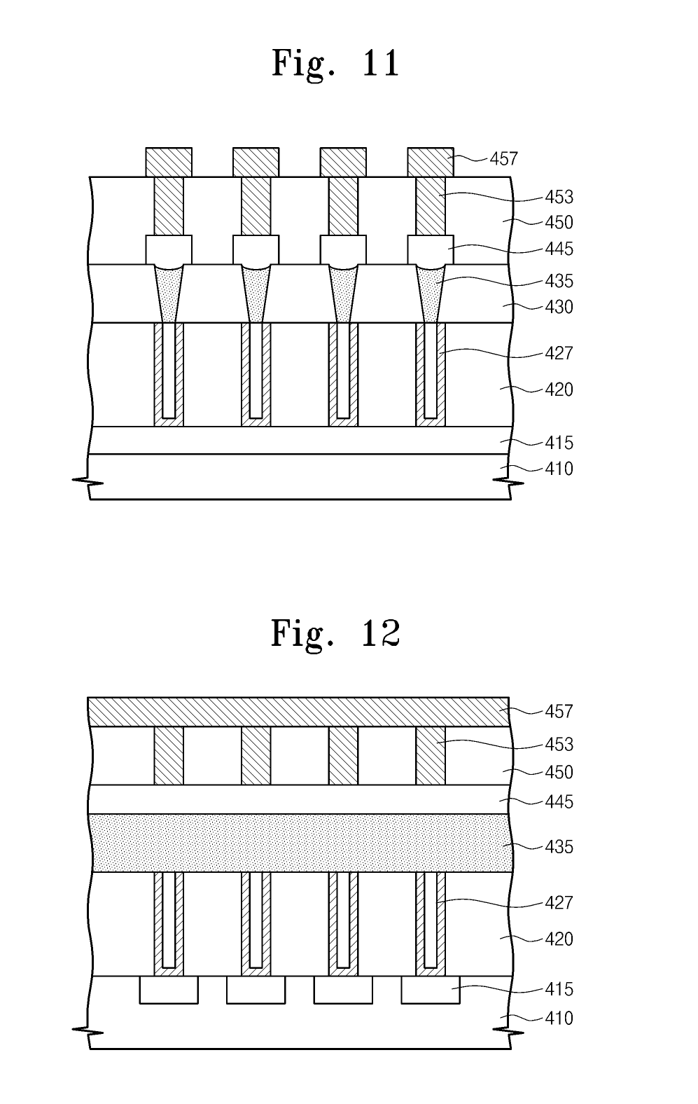

FIGS. 10 to 12 show still another example of a memory cell array according to the inventive concept. The memory cell array shown in FIGS. 10 to 12 is substantially identical to that shown in FIGS. 4 to 6 except for the shape of bottom electrodes. Therefore, only the part of the memory cell array including the bottom electrodes will be described in detail and elements which are similar to those of the memory cell array shown in FIGS. 4 to 6 will be designated by similar reference numerals except that the reference numeral used in FIGS. 10 to 12 will be preceded by the number “4” instead of the number “2”.

A respective set of bottom electrodes 427 is disposed on each wordline 415, and the bottom electrodes 427 in each set are spaced apart from each other by a predetermined distance along the length of the respective wordline 415. Therefore, the bottom electrodes 427 are disposed on the wordlines 315 in a matrix. Furthermore, the bottom electrodes 427 each have an annular upper surface. That is, the bottom electrodes 427 are cylindrical and may have a closed bottom end. Also, the width of each of the bottom electrodes 427 may be smaller than the width of each of the wordlines 415.

A method of fabricating a variable resistance memory device, according to the inventive concept, will now be described hereinafter with reference to FIGS. 4-6, 13A to 25A, and 13B-25B.

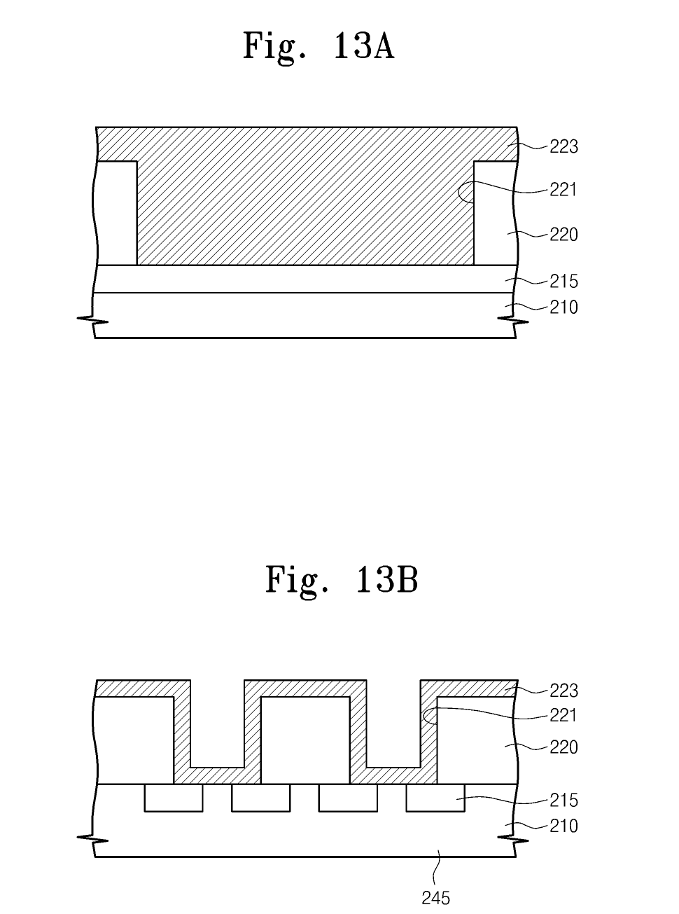

Referring to FIGS. 13A and 13B, wordlines 215 and select elements (D in FIG. 2) are provided on a silicon substrate 210. Then, a bottom insulating first layer 220 is formed on the silicon substrate 210. The bottom insulating layer 220 is formed of, for example, an oxide. The first bottom insulating layer 220 is patterned to form trenches 221.

The shapes of the trenches 221 depend on the desired shape of the bottom electrodes to be formed. For example, when dash-shaped bottom electrodes 227 are formed (see FIGS. 4 to 6), the trenches 221 are formed as linear openings extending in a first direction parallel to the wordlines 215.

Next, a conductive layer 223 conforming to the topography of the structure may be formed on the bottom insulating layer 220. As will be clear from the description that follows, the bottom electrodes 227 (FIGS. 4 to 6) are formed from the conductive layer 223. The conformal conductive layer 223 (and hence, the bottom electrodes 227) may be formed of at least one material selected from the group consisting of Ti, Tsiₓ, TiN, TiON, TiW, TiAlN, TiAlON, TiSiN, TiBN, W, WSiₓ, WN, WON, WSiN, WBN, WCN, Ta, TaSiₓ, TaN, TaON, TaAlN, TaSiN, TaCN, Mo, MoN, MoSiN, MoAlN, NbN, ZrSiN, ZrAlN, Ru, CoSiₓ, conductive carbon, and Cu.

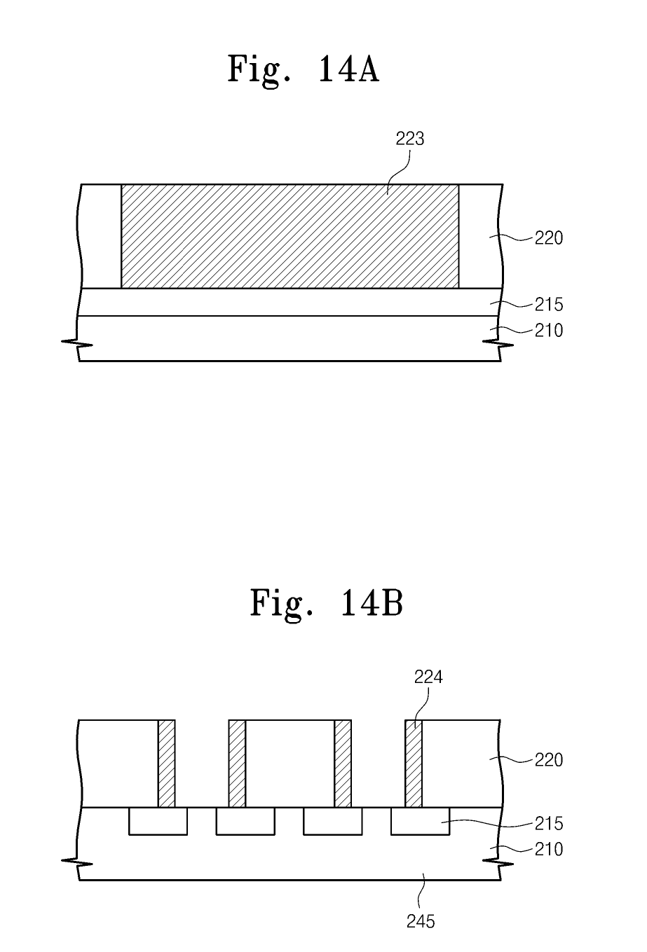

Referring to FIGS. 14A and 14B, the conformal conductive layer 223 is anisotropically etched to remove the conductive layer 223 from the top surface of the bottom insulating layer 220 and from the exposed top surface of the silicon substrate 210. As a result, a bottom electrode pattern 224 is formed on the sidewalls of the trenches 221. In this example, the bottom electrode pattern 224 is a line type of pattern. Accordingly, each segment of the bottom electrode pattern 224 has a width corresponding to the thickness of the conductive layer 223 that was formed on the bottom insulating layer 220. With this technique, the widths of the segments of the bottom electrode pattern 224 may be smaller than those of the wordlines 215 and below the limits imposed by the resolution of a typical photolithography process.

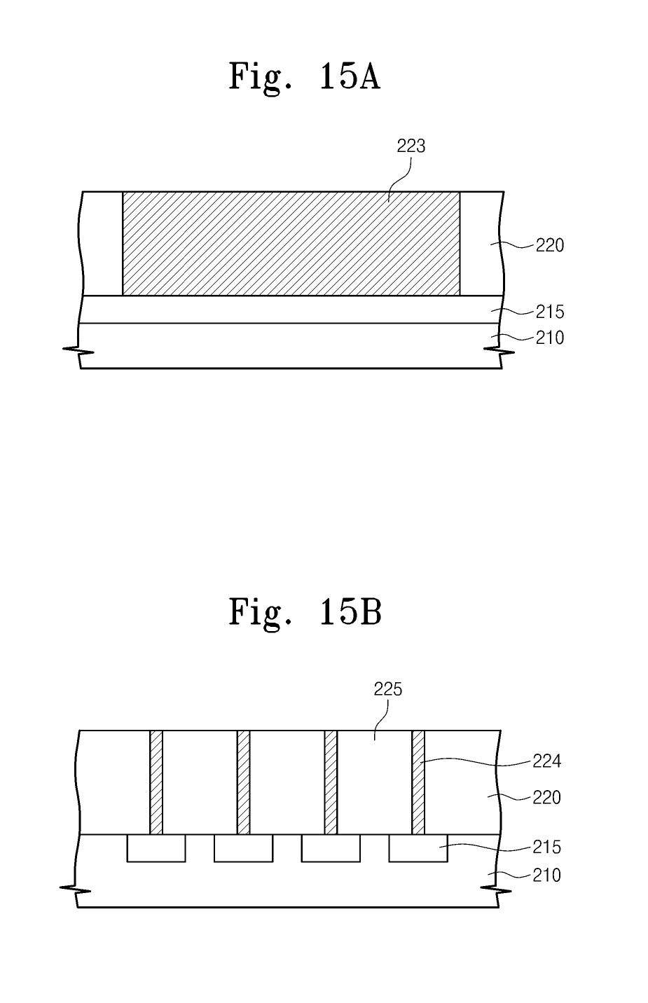

Referring to FIGS. 15A and 15B, a second bottom insulating layer 225 is formed to fill the trenches and cover the bottom insulating layer 220, and the second bottom insulating layer 225 is planarized to expose the top surface of the bottom electrode pattern 224.

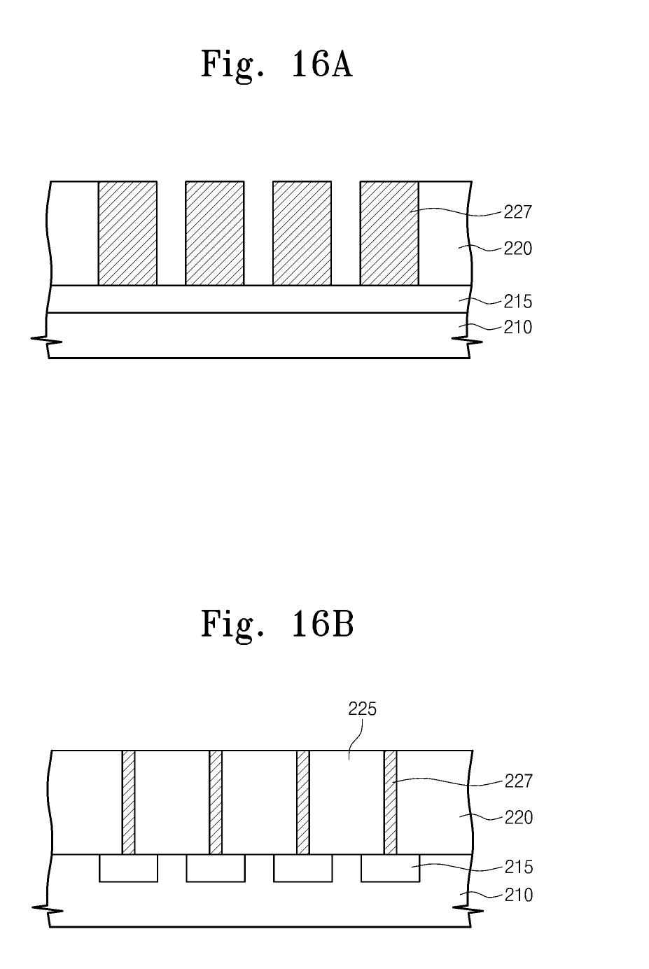

Referring to FIGS. 16A and 16B, the bottom electrode pattern 224 is patterned in a second direction, transversely to the first direction, to form bottom electrodes 227 which are each elongated in the first direction. Also, a respective set of the bottom electrodes 227 is disposed on each wordline 215, and the bottom electrodes 227 of each set are spaced apart from each other along the length of the wordline 215. In this embodiment, the critical dimension (CD) of the bottom electrodes 227 (i.e., their width) is about 100 nanometers or less. In fact, the CD of the bottom electrodes 227 may be 70 nanometers or less.

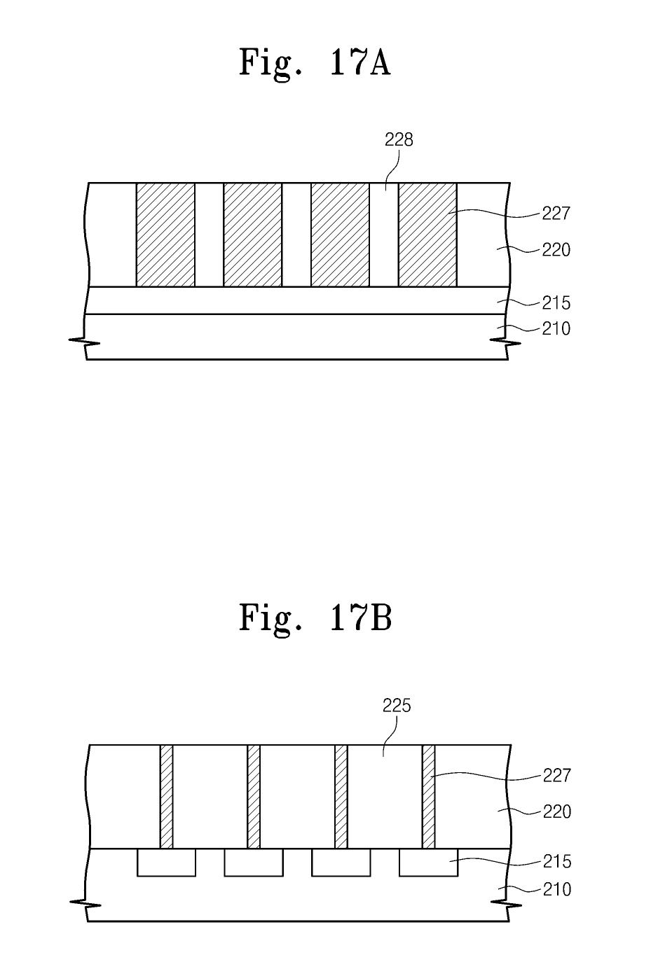

Referring to FIGS. 17A and 17B, a third bottom insulating layer 228 is formed to fill the space between the bottom electrodes 227.

Although the method of fabricating a variable resistance memory device has been described so far with respect to the forming of bottom electrodes in the form of dashes as shown in FIGS. 4 to 6, it will be understood that the method may also apply to the forming of the circular or quadrangular pillar type or cylindrical type of bottom electrodes shown in FIGS. 7 to 12. For example, the circular or quadrangular pillar type of bottom electrodes 327 can be formed by forming holes in a bottom insulating layer on a semiconductor substrate and filling the holes with a conductive material. The cylindrical bottom electrodes 427 can be formed by forming contact holes in a bottom insulating layer on a semiconductor substrate, then forming a conductive layer along the surfaces that delimit the contact holes, and filling the remaining portions of the contact holes with insulating material.

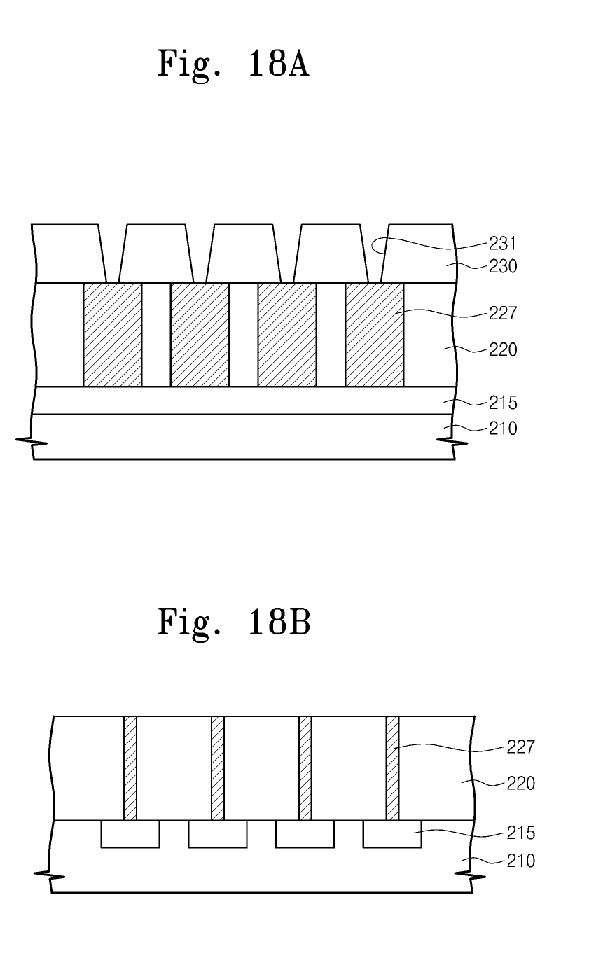

Referring to FIGS. 18A and 18B, an interlayer dielectric layer 230 is formed on the bottom insulating layer 220. The interlayer dielectric layer 230 is patterned to form trenches 231 therein.

The interlayer dielectric layer 230 may be formed of silicon oxide such as, for example, borosilicate glass (BSG), phosphosilicate glass (PSG), borophosphosilicate glass (BPSG), plasma enhanced tetraethylorthosilicate (PE-TEOS) or a high density plasma (HDP) silicon oxide. Alternatively, the interlayer dielectric layer 230 may be formed of a metal-based insulating material such as aluminum oxide (AlO), tantalum oxide (TaO) or hafnium oxide (HfO).

The trenches 231 are elongated in a second direction extending transversely, e.g., perpendicular, to the first direction. The trenches 231 also expose top surfaces of the bottom electrodes 227. More specifically, each trench 231 exposes the top surfaces of one column of the bottom electrodes 227. Furthermore, the top of each trench 231 may be wider than its bottom. Also, the width of the bottom of each trench 231 may be smaller than the length (major axis) of each bottom electrode 227 across which the trench 231 extends. That is, only part of each of the top surfaces of the dash-shaped bottom electrodes 227 may be exposed by the trenches 231.

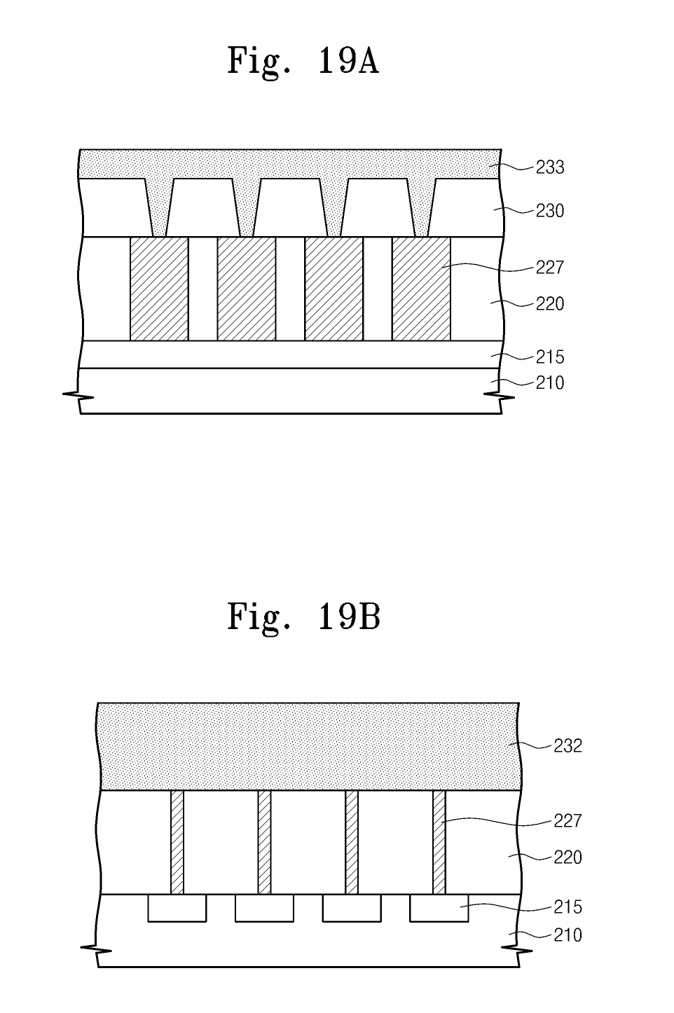

Referring to FIGS. 19A and 19B, a variable resistance material 233 is deposited on the interlayer dielectric layer 230. The variable resistance material 233 may be a phase change material such as chalcogenide. More broadly, though, the variable resistance material 233 may be a compound of at least two materials selected from the group consisting of Te, Se, Ge, Sb, Bi, Pb, Sn, Ag, As, S, Si, P, O, and C. That is, the variable resistance material 233 may be formed of Ge—Sb—Te, As—Sb—Te, As—Ge—Sb—Te, Sb—Sb—Te, Ag—In—Sb—Te, In—Sb—Te, 5A group element-Sb—Te, 6A group element-Sb—Te, 5A group element-Sb—Se or 6A group element-Sb—Se.

The variable resistance material 233 may be deposited on the interlayer dielectric layer 230 by means of physical vapor deposition (PVD) or chemical vapor deposition (CVD). For example, the variable resistance material 233 may be formed by high pressure CVD (HP-CVD) or atomic layer deposition (ALD) so as to have superior step coverage. Although not illustrated in the figures, an interfacial layer may be disposed between the variable resistance material 233 and the bottom electrodes 227.

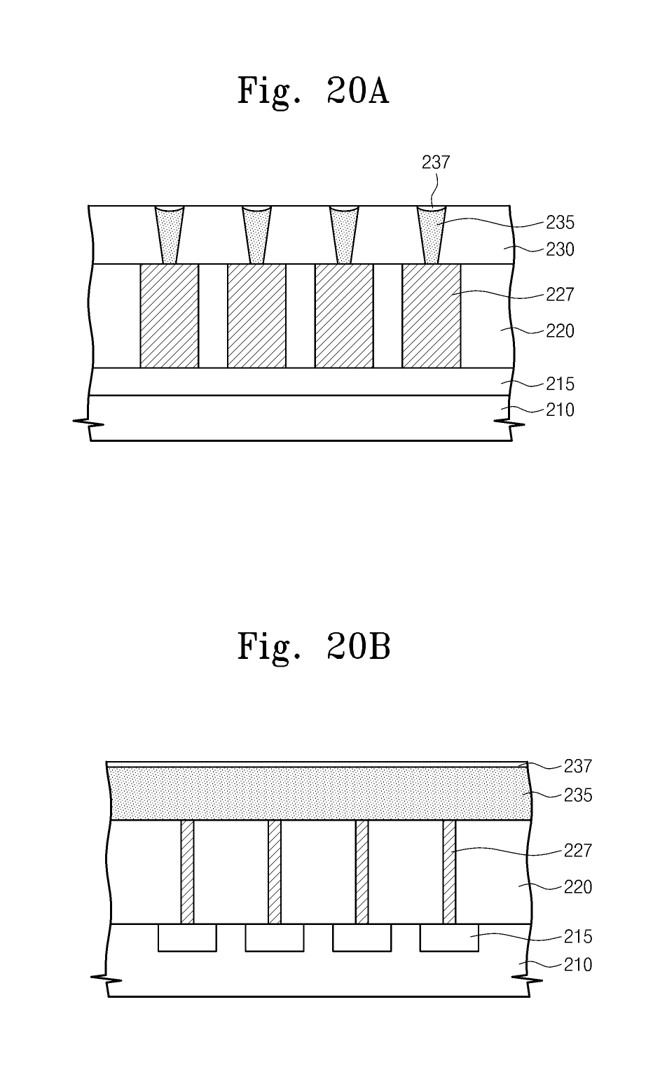

Referring to FIGS. 20A and 20B, the variable resistance material 233 is planarized down to a top surface of the interlayer dielectric layer 230 to form a pattern of variable resistance material 235 in the interlayer dielectric layer 230. The variable resistance material 233 may be planarized by means of a chemical mechanical polishing (CMP) process or an etch-back process. Unfortunately, though, contaminants 237 produced during the planarization process may remain on the variable resistance material 235.

The contaminants 237, if left untreated, could decrease the conductivity between the variable resistance material 235 and the top electrodes 245 (refer back to FIGS. 4 to 6). That is, the contaminants 237 have the potential to increase the resistance of variable resistance memory cells to a value higher than that designed for, so much so that the variable resistance memory cells would operate as OFF cells. Therefore, the structure is etched after the planarizing of the variable resistance material 233 to remove the contaminants 237.

For example, the etching may be performed by exciting inert gas to generate plasma, and facilitating a reaction between the plasma and the contaminants 237 on the variable resistance material 235. In an example of such a plasma etching process, an inert gas such as Ar, He, Ne, Kr, or Xe is introduced into the processing chamber of an etching apparatus, and an RF bias is applied to an upper portion of the chamber of the etching apparatus and a ground voltage is applied to a lower portion thereof. For example, the RF bias is between 0 and 300 watts, the power level used to excite the inert gas is in a range of 100 to 600 watts, and the pressure in the processing chamber is controlled to be within a range of 1 to 100 mTorr. Moreover, the etching process is designed so as to provide an etch selectivity of the contaminants 237 to the second interlayer dielectric of at least 2 to 1.

Furthermore, a compound such as CxFx, Cl2, or HBr may be added to the inert gas. The amount of the compound added to the inert gas may be smaller than the amount of the inert gas. In particular, the amount of the compound added to the inert gas may be at most 50 percent with respect to the total amount of the inert gas and the compound.

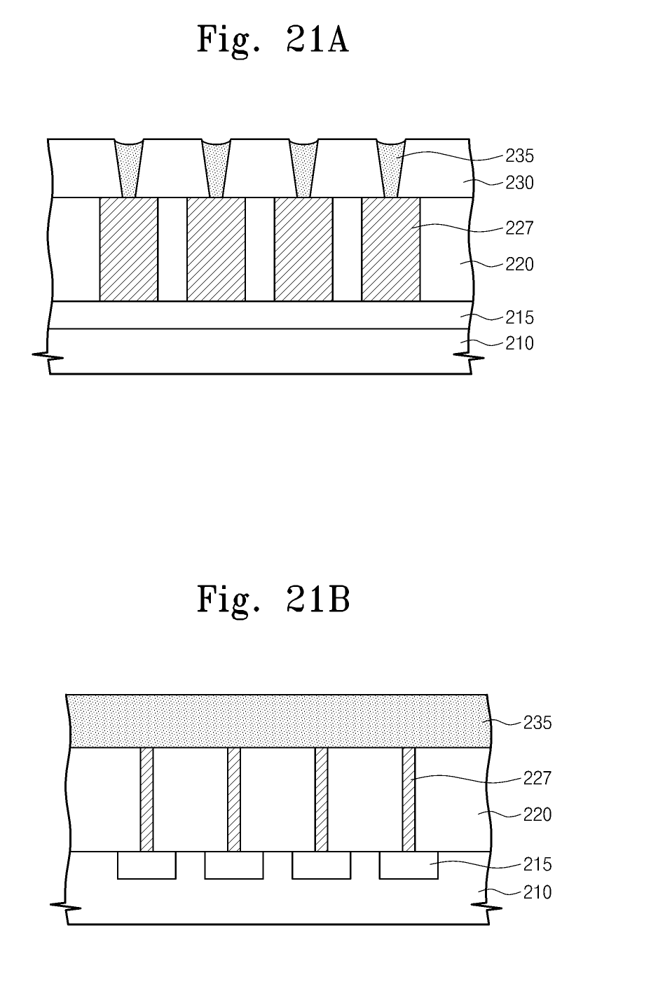

FIGS. 21A and 21B show the variable resistance material 235 once the contaminants 237 have been removed therefrom by the etching process.

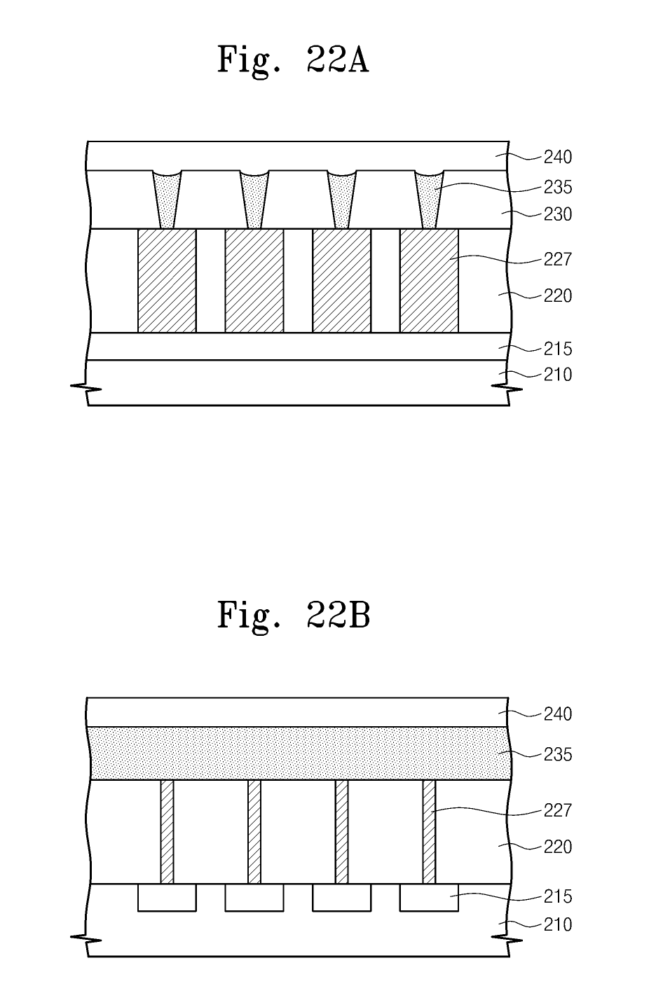

Referring to FIGS. 22A and 22B, a conductive layer 240 for the top electrodes 245 is formed on the interlayer dielectric layer 230. The conductive layer 240 may be formed of at least one material selected from the group consisting of Ti, TiSiₓ, TiN, TiON, TiW, TiAlN, TiAlON, TiSiN, TiBN, W, WSiₓ, WN, WON, WSiN, WBN, WCN, Ta, TaSiₓ, TaN, TaON, TaAlN, TaSiN, TaCN, Mo, MoN, MoSiN, MoAlN, NbN, ZrSiN, ZrAlN, Ru, CoSi, NiSi, conductive carbon, and Cu.

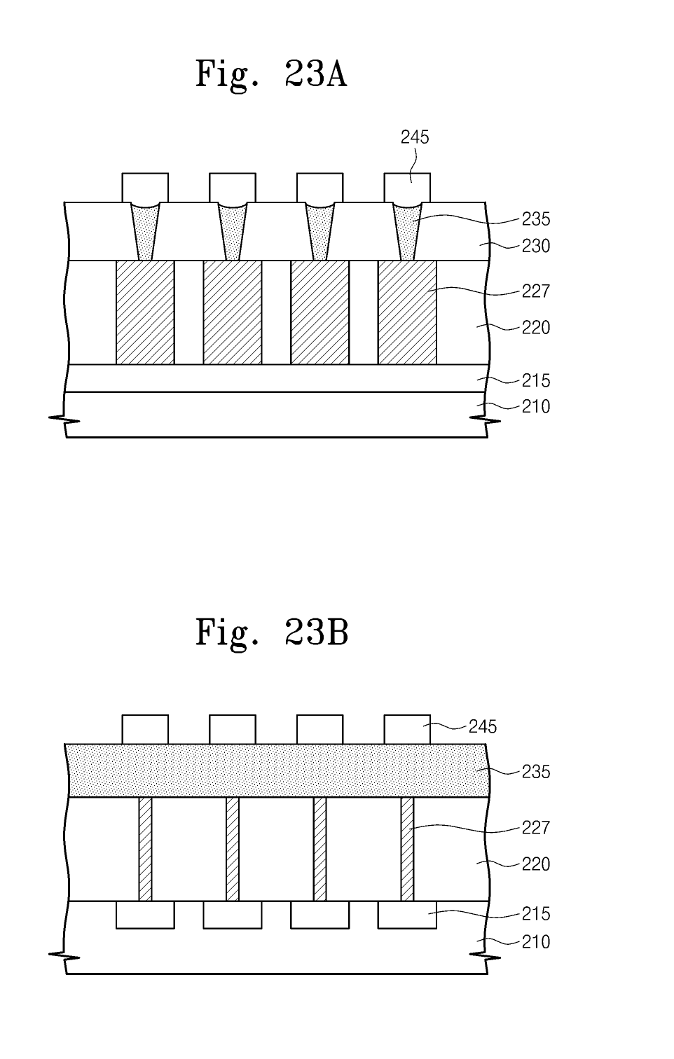

Referring to FIGS. 23A and 23B, the conductive layer 240 is patterned to form top electrodes 245 on the pattern of variable resistance material 235. In this embodiment, the top electrodes 245 are flat and plate-shaped and are vertically juxtaposed (aligned) with the bottom electrodes 227, respectively. Alternatively, and as shown in FIGS. 4 to 6, the top electrodes 245 may be elongated in a direction extending transversely relative to the longitudinal direction of the wordlines 215. In the latter case, as was mentioned above, the top electrodes 245 may serves as bitlines.

As described with reference to FIGS. 20A, 20B, 21A, and 22B, the contaminants 237 produced during the planarization of the variable resistance material 235 are removed by means of an etching process. For this reason, top surfaces of the elements of the variable resistance material 235 are concave in a direction toward the substrate 210. Thus, the top electrodes 245 formed on the variable resistance material 235 protrude toward the substrate 210.

Although not illustrated in the figures, a heat-loss preventing layer may be formed between the variable resistance material 235 and the top electrodes 245. The heat-loss preventing layer may be formed to a small thickness on the variable resistance material 235 and in conformance with the topography of the variable resistance material. The heat-loss preventing layer can be formed of SiN, PE-SiN or SiON, for example. Such a heat-loss preventing layer would serve to prevent heat from dissipating from the variable resistance material 235 when the material is heated by the bottom electrodes 227. Moreover, the heat-loss preventing layer can serve as an etch-stop layer during a process of patterning the variable resistance material 233.

Also, a barrier layer may be formed between the variable resistance material 235 and the top electrodes 245 to prevent the diffusion of material therebetween. Such a barrier layer may include at least one of Ti, Ta, Mo, Hf, Zr, Cr, W, Nb, V, N, C, Al, B, P, O, and S. More specifically, such a barrier layer may include at least one of TiN, TiW, TiAlN, TiSiC, TaN, TaSiN, WN, MoN, and CN.

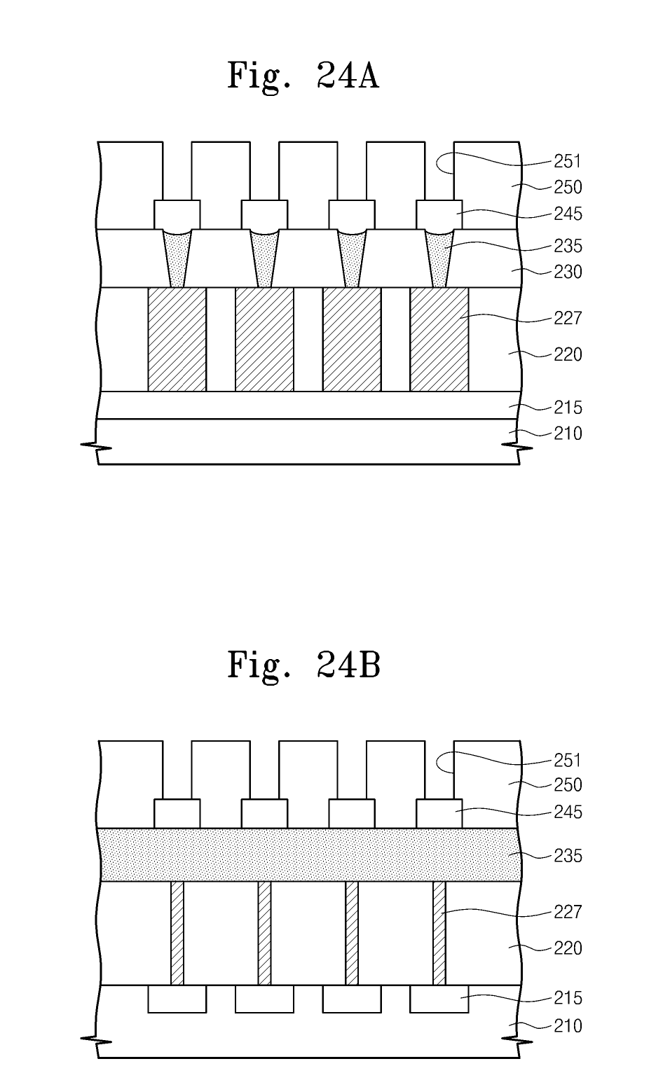

Referring to FIGS. 24A and 24B, another interlayer dielectric layer 250 is formed on the top electrodes 245 and interlayer dielectric layer 230. The second interlayer dielectric layer 250 is patterned to define contact holes 254 corresponding to and exposing the top electrodes 245.

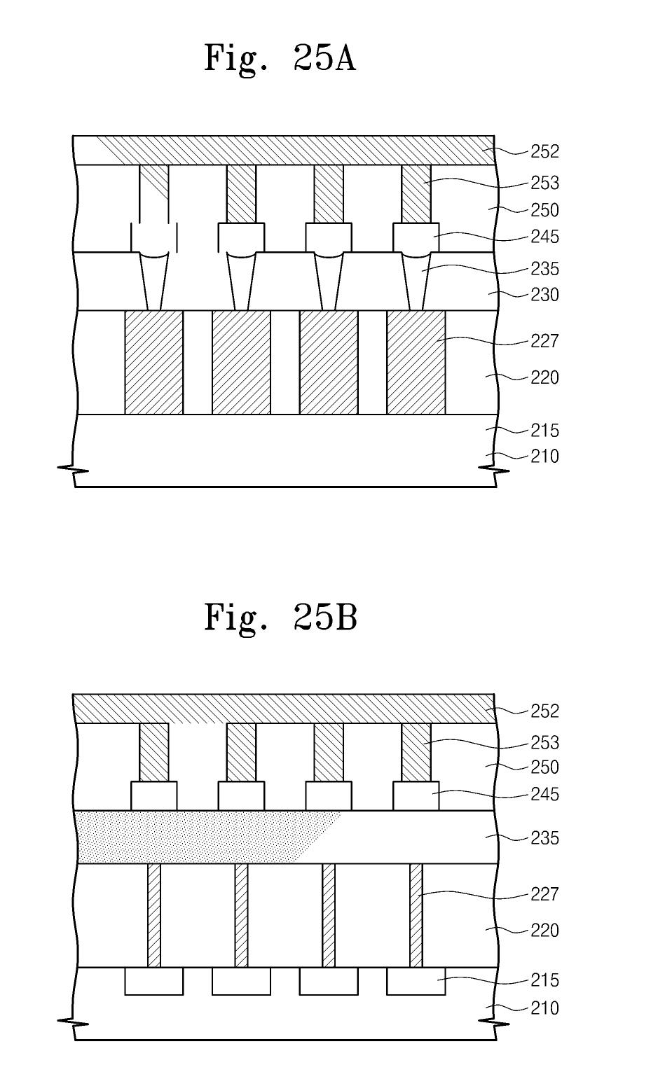

Referring to FIGS. 25A and 25B, the contact holes 251 re filled with conductive material, and a conductive layer 252 is formed on the interlayer dielectric layer 250. The conductive layer 252 may be patterned to form bitlines (such as bitlines 257 shown in FIGS. 4 to 6). The conductive layer 252 (bitlines 257) and the top electrodes 245 are connected by the conductive material filling the contact holes 251. That is, the conductive layer 252 (bitlines 257) and the top electrodes 245 are connected by vias 253.

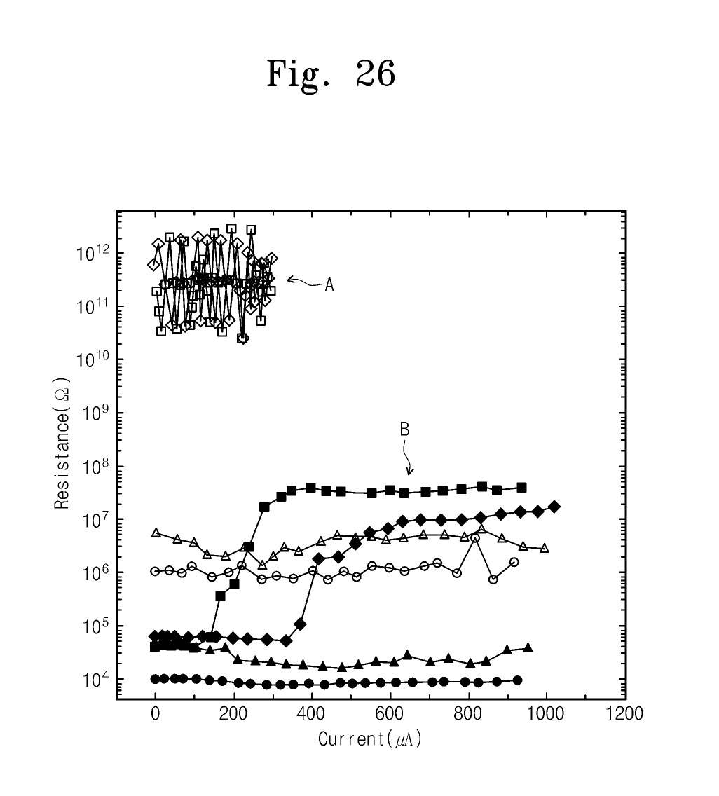

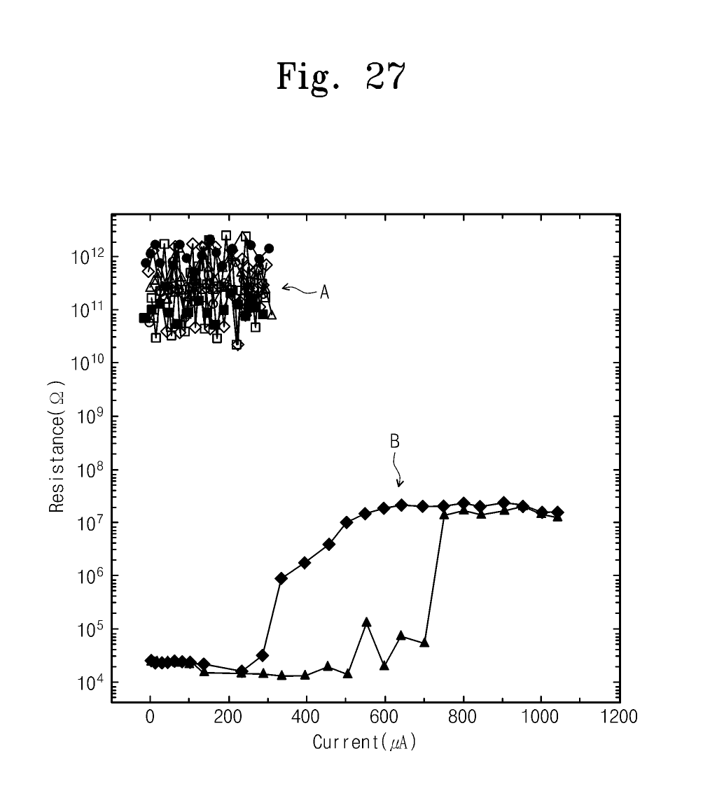

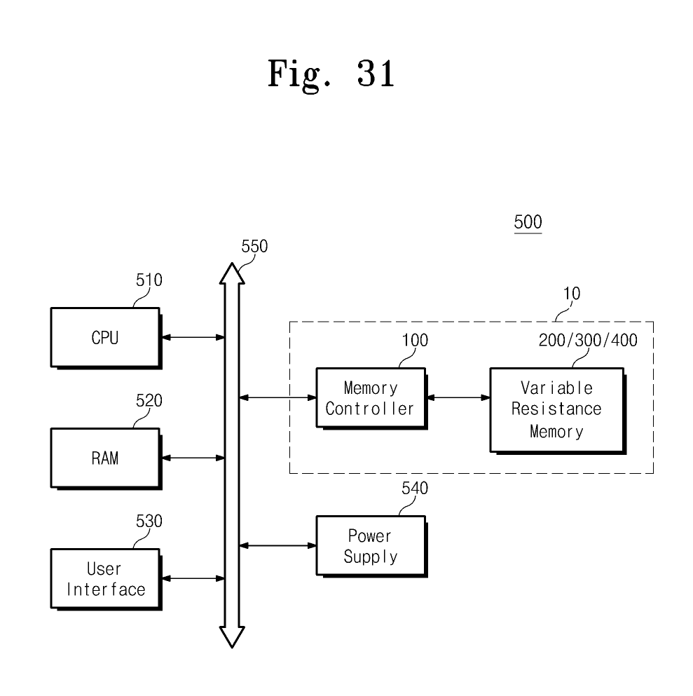

FIGS. 26 to 30 illustrate results of a performance test of variable resistance memory cells. Specifically, FIG. 26 illustrates a performance test of variable resistance memory cells fabricated without using an etching process for removing the contaminants from the variable resistance material. On the other hand, FIGS. 27 to 30 illustrate results of a performance test of variable resistance memory cells fabricated using respective etching processes having higher and higher etching rates for removing contaminants from the variable resistance material (FIG. 27 showing test results for memory cells fabricated using an etching process having the lowest of the etching rates and FIG. 30 showing test results for memory cells fabricated using an etching process having the highest of the etching rates). In these graphs, reference symbol “A” points to the results showing the variable resistance memory cells operating as OFF cells, and reference symbol “B” points to the results showing variable resistance memory cells having a resistance value which is approximately that of the designed for value.

As can be seen in FIG. 26, there were a number of variable resistance memory cells operating as OFF cells. Furthermore, among the variable resistance memory cells “B”, there were a number of cells which do not operate normally.

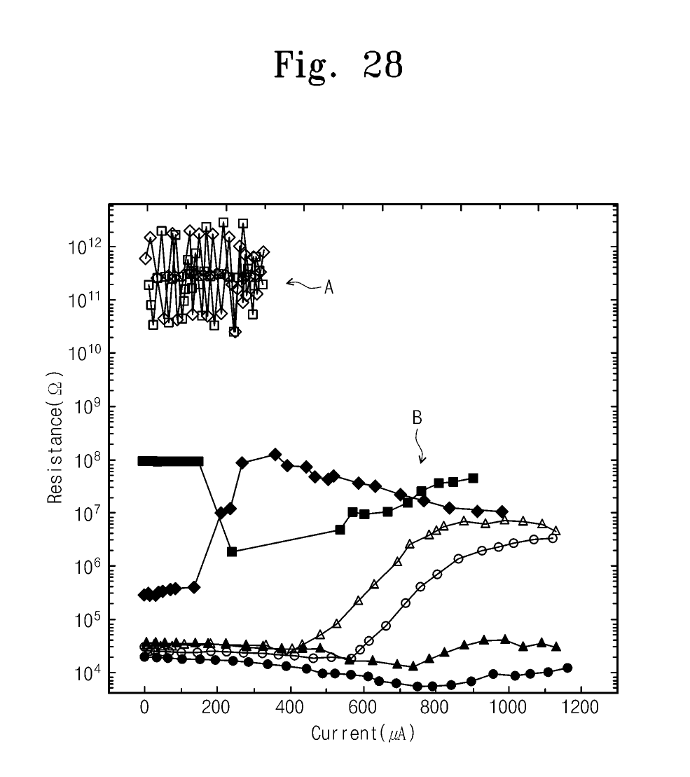

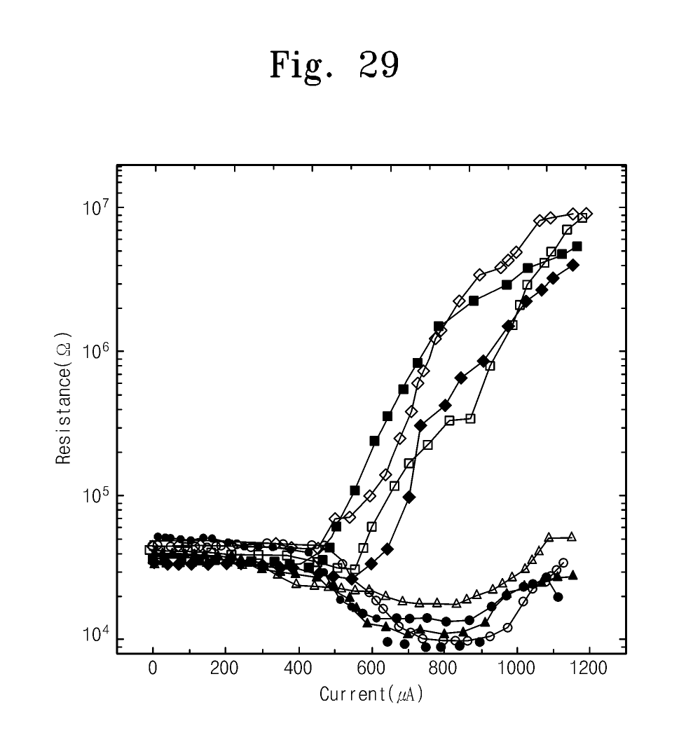

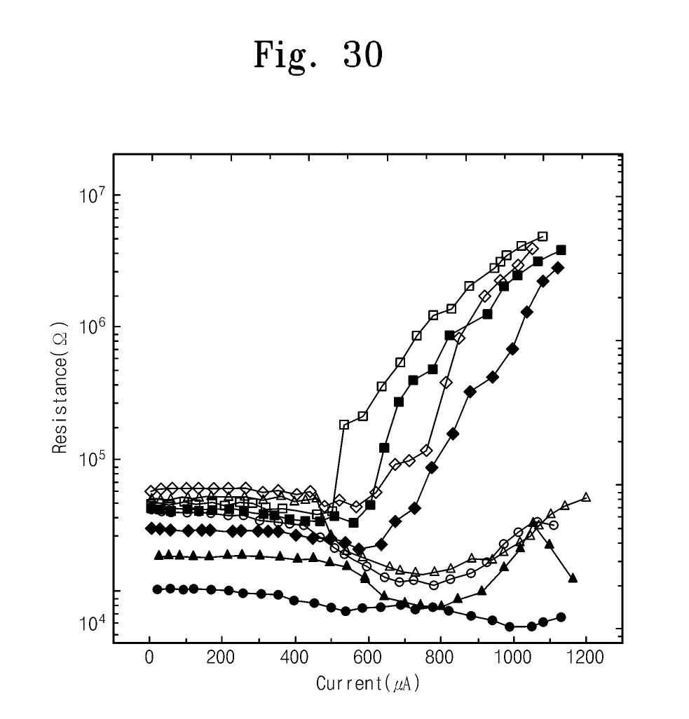

Referring to FIGS. 27 and 28, although there were variable resistance memory cells “A” operating as OFF cells, the variable resistance memory cells “B” having a resistance value close to the designed for value exhibited an improved performance over those fabricated when no etching process was used to remove contaminants from the variable resistance material. Referring to FIGS. 29 and 30, these test results showed no OFF cells and the variable resistance memory cells operated normally. That is, the performance of variable resistance memory cells was improved when an etching process was performed to remove the contaminants 237. Therefore, practicing the method according to the inventive concept can improve the yield of variable resistance memory devices.

FIG. 31 illustrates a computer 500 including a memory 10 of the type shown in FIG. 1. The computer 500 includes a central processing unit (CPU) 510, a random access memory (RAM) 520, a user interface 530, a power 540, and the memory 10.

The memory 10 is electrically connected to the CPU 510, the RAM 520, the user interface 530, and the power 540 through a system bus 550. Data provided through the user interface 530 or processed by the CPU 510 is stored in the memory 10. The memory 10 includes a controller 100 and a variable resistance memory device 200, 300 or 400 (i.e., any of the memory cell arrays described hereinabove).

The memory 10 may be a solid-state disk/drive (SSD). In this case, the computer 500 may be booted up quickly. Also, and although not illustrated in the figures, the memory 10 may further include an application chipset, an image processor, etc.

Finally, embodiments of the inventive concept have been described herein in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiments described above but by the following claims.

What is claimed is:

1. A method of fabricating a variable resistance memory device, comprising:
forming bottom electrodes on a semiconductor substrate;
forming on the bottom electrodes an interlayer dielectric layer having trenches that expose the bottom electrodes;
forming variable resistance material on the interlayer dielectric layer to such a thickness as to fill the trenches;
planarizing the variable resistance material to remove variable resistance material from atop the interlayer dielectric layer and leave variable resistance material in the trenches; and
subsequently removing contaminants, produced by the planarizing, from the variable resistance material in the trenches, wherein the removing of the contaminants comprises etching the variable resistance material after the planarizing has been terminated; and
forming a top electrode on the variable resistance material.

2. The method as set forth in claim 1, wherein the etching of the variable resistance material comprises producing plasma, and exposing the contaminants to the plasma.

3. The method as set forth in claim 2, wherein the producing of the plasma comprises exciting a gas selected from the group consisting of Ar, He, Ne, Kr, and Xe.

4. The method as set forth in claim 2, wherein the producing of the plasma comprises exciting a gaseous mixture of at least one of a carbon-fluorine compound, Cl₂, and HBr, and one of Ar, He, Ne, Kr, and Xe.

5. The method as set forth in claim 1, wherein the forming of the interlayer dielectric layer comprises forming an interlayer dielectric layer having trenches that expose the bottom electrodes, are elongated, and are parallel to each other.

6. The method as set forth in claim 1, wherein the forming of the interlayer dielectric layer comprises forming an interlayer dielectric layer having trenches whose upper portions are wider than their lower portions.

7. The method as set forth in claim 1, wherein the variable resistance material is formed of a phase change material that assumes an amorphous state when at one temperature and a crystalline state when at another temperature, and which has different resistances when in its amorphous and crystalline states.

8. The method as set forth in claim 1, wherein the variable resistance material is formed of at least two compounds selected from the group consisting of Te, Se, Ge, Sb, Bi, Pb, Sn, Ag, As, S, Si, P, O, and C.

9. The method as set forth in claim 1, wherein the variable resistance material is formed of chalcogenide.
